(19) United States
(12) Patent Application Publication
(10) Pub. No.: US 2018/0187322 A1
(43) Pub. Date: Jul. 5, 2018

(54) Proportional-Integral-Derivative Radio Frequencies Synchronized plasma Coupled Harmonic Closed Loop Feedback Oscilllator to Maintain a Constant Resonance Oscillating Harmonic Enhanced Exothermic Reaction Within Metal Lattice During Hydrogen Loading to Generating Efficient Exothermic Thermoelectric, Mechanical Power and Graphene Nano Tubes

(71) Applicant: John Timothy Sullivan, Marriottsville, MD (US)

(72) Inventor: John Timothy Sullivan, Marriottsville, MD (US)

(21) Appl. No.: 15/646,338

(22) Filed: Jul. 11, 2017

Related U.S. Application Data
(60) Provisional application No. 62/360,725, filed on Jul. 11, 2016.

(51) Int. Cl. C25D 5/50; C08J 3/16; C23C 16/02; C25B 9/04; C25B 11/02; C25B 11/04; C01B 32/19; C25B 1/34

(52) U.S. Cl. CPC C25D 5/505; C08J 3/16; C23C 16/0218; C25B 9/04; C25B 1/34; C25B 11/0436; C01B 32/19; C23C 16/0245; C25B 11/02

(57) ABSTRACT

Radio frequency (RF) power, and in particular microwaves, are used as a source of heat for plasma Exothermic Enhanced Reactions (EERs) in a metal lattice, into which hydrogen is loaded in the presence of lithium or graphene.

This application claims the benefit of U.S. Provisional Patent Appl. Ser. No. 62/360,725, filed Jul. 11, 2016.

### SUMMARY OF THE INVENTION

The invention relates to the use of radio frequency (RF) power, and in particular microwaves, to as a source of heat for plasma Exothermic Enhanced Reactions (EERs) in a metal lattice, into which hydrogen is loaded in the presence of lithium or graphene.

In one preferred embodiment, a reactor uses the RF power to heat metal materials with lithium or graphene, the metal materials being subjected to pressure loading of hydrogen, deuterium, or hydrogen-containing gases such as natural gas, causing within the lattice of the electrode.

In another preferred embodiment, a dry or wet deuterium, lithium chloride electrolysis cell uses the RF power to heat metal electrodes within the electrolyte.

In either of the preferred embodiments, a closed feedback loop may be used to prevent a runaway reaction and control oscillations in the electrode lattices. The microwave heated materials generate plasma EERs that produce an RF microwave output within a metal lattice. A radio frequency sensor or sensors capture the EER radio frequency lattice output oscillations that are 180 degrees out of phase from the RF input source. Through software and hardware, the RF is harmonically synchronized or coupled between the input source RF with the lattice output RF to create harmonic oscillations with local interaction between the source and reaction RF within a closed feedback loop. The resonance lattice reaction between input and output RF in a closed feedback loop keeps the oscillation in a constant state that results in an improved reduced input power to maintain a constant output power. As the lattice metal heats up using the RF power with lithium and hydrogen gas pressure during cathode hydrogen loading between the lattice's super abundant vacancies, a switching magnetic field can create a vortex that can cause a ferromagnetic flip within the Face Center Cube (FCC), Body-Center-Cube (BBC) or Hexagonal Close Packed (HCP) alignment of the lattice. This mismatched magnetic alignment within the lattice causes the FCC, BBC or HCP to jump out of alignment and cause a spin of the FCC, BBC, HCP or other transitional metals to spin like a top at microwaves speeds to create a microwave motor vortex swirl that melts nearby materials with friction heat. Once the Vortex is in motion, it melts metals that are in contact with the spinning metals and it also produces an RF signal. The oscillating lattice will try to find a harmonic equilibrium.

The object of the invention is to not let the lattice find harmonic equilibrium, but rather the object of the feedback loop is to increase as many surface oscillations as possible by harmonic oscillation of the lattice using RF waveguides that create a rotating plasma vortex's and RF reflections on the surface of the materials to promote as many vortices and lattice oscillations as possible by putting the FCC and other transitional metals in motion by electromotive disturbances. It is preferred that some of the materials used have ferromagnetic properties so that they can also be mixed with copper, ruthenium, rhodium, graphene and other conductive materials to increase the conductive value.

The metal transitional foils, foams, wire knitted mesh, or powdered materials can be constructed under hydrogen, deuterium, lithium chloride, or gas pre-loaded pressures and mixed with lithium or graphene as a readymade reaction material. The RF can range from a Hertz to Terahertz range with the optimal ranges in the MHz to THz range. The electronic and software (PID) feedback loop prevents a run-away reaction to control the oscillations at a maximum set point level to prevent a chain reaction as shown in FIG. 1.

FIG. 1 shows a block diagram of the RF PID control system that keeps reaction microwaves in a constant state of harmonic resonance oscillations or “looped signal,” that is, a signal which travels in a continuous loop between the RF source and the reaction microwaves released sensor from the EER reaction fuels.

The PID loop prevents a runaway by limiting the fuel source and the microwave input power, by limiting the current or the RF frequencies. The phase angle between the lattice oscillation and the transmitter can control the heat in the lattice reaction. For example, if the lattice frequencies are 180 degrees out of phase, it will reduce the heat of the lattice and control the temperature of the reaction. The closed feedback loop creates a natural harmonic resonance oscillation between the RF transmitter source and EER lattice reaction output microwave's EER reactions picked up by the microwave sensor for the highest efficiencies possible while maintaining a constant fuel supply. The PID loop controls the magnetrons or LDMOS's RF solid state power transistors with precise gate timing to heat the reaction materials up until they vibrate to generate a microwave energy output. The solid state LDMOS Mosfet can be both the transmitter and receiver, alternating between the two states, or a separate sensor can be used. The microwave energy released from the heated fuels will be captured with RF sensors, and the vibrating materials will vary their frequencies due to a variable resonance that is dependent on many variables such as the waveguide chamber design, the types and ratio of transitional metals, lithium, and gas fuels used, heat and the amount of fuel consumed over time and at startup.

The PID RF feedback loop will compensate for changes in the variable frequencies over time to keep the RF source in synch with the RF vibrating heated materials for the most optimum heating response while maintaining a constant fuel supply. For example, as the fuel level decreases, more fuel such as H2, natural gas or D2 gas will be added at a level to prevent a runaway. The PID loop will prevent a thermal runaway by adjusting the fuel input levels and the microwave input power levels to keep the heater reactor at a desired pre-programmed setpoint. The fuel feedback can be measured in fuel pressure or heat output. The RF microwave or THz energy output from the vibrating materials can be used as a waste by-product to drive space propulsion engines such as an electromotive (EM) drive. Also the reaction temperature can heat a fluid or a gas to spin a turbine and thereby spin an electrical generator to produce electricity, or the difference in potential from many cells can produce thermoelectric electricity directly as a high temp fuel cell. The PID loop works similarly to pushing a child on a swing. Once the swing is in motion, if you know when to push it takes very little energy to keep the swing in motion. The present invention works in a similar fashion at Hz to THz speeds.

The microwave heater reaction material can be metal powders such as nickel or titanium and other transitional materials, in which case they will clump when heated to form a solid material that may reduce performance. A woven stainless steel mesh wire or metal foam with a high surface area and high melt temperature can be carbonyl nickel coated and then placed into a high temperature vacuum chamber with methane to grow graphene on the surface of the nickel coated wire mesh, with or without lithium for a highly conductive EER reactive surface. The hydrogen from the methane is embedded on the surface of the nickel and the carbon chains from graphene on the surface of the nickel coated stainless steel wire mesh acts as a host to form the reactive surface under heat and hydrogen or deuterium gas pressure loading. The lithium can be added during the graphene process or during the reactor construction. Other transitional metals such as ruthenium, copper, palladium, carbide and other materials can be added during the high vacuum furnace processing. When the nickel or titanium is spent overtime the wire mesh can be recoated and reused over and over again where powders cannot. Also the EER reaction is a surface event and dense thick metals are not as efficient as thin coating. The materials can also be honeycomb ceramic materials similar to a catalytic converter used in exhaust gases with coated transitional materials and lithium and hydrogen or deuterium gas. A possible option is to allow a runaway chain reaction to produce a fuel or reaction controlled by the microwave oscillations in a runaway loop. A second safety feature is to have a second microwave source and sensor to produce a wave form 180 degrees out of phase to prevent an oscillation runaway.

Another novel feature of the invention is that it can produce electricity directly from the EER reaction using thermoelectric thermocouple electrodes and microwaves as the heat source, with a feedback loop to heat electrodes 57,58 shown in FIG. 14 with a cell or cells in parallel or series, by mixing the positive and negative cells with lithium, hydrogen and a combination of the materials illustrated in FIG. 12, 13,14 to produce a direct coupled thermoelectric thermocouple cell or cells with a different in potential to drive an electrical load, as shown in FIG. 14. The heat from the reactive cells can also be harnessed to heat a fluid or gas to perform work.

Another novel feature is that the thermocouple electrode materials can be stacked to produce a voltage under heat with an EER, using RF heating and other sources with a controlled PID feedback loop. The multi-stacked materials in FIG. 14 can be a combination of the materials listed in FIG. 12 for respective electrodes 57,58, to produce an EER reaction and voltage at the same time with the presence of heat, current, hydrogen, lithium, lithium chloride and a mixture of transitional materials and conductive materials such as graphene, copper, Iron, graphite, carbide etc. The multi-stacked cells in FIG. 14 alternate every other cell similar to a battery to produce a higher voltage by stacking more anode/cathode cells in series or parallel to increase the voltage level that is enhanced by the heat generated from the EER reaction. FIG. 12 lists a combination of materials that can be stacked as shown in FIG. 14 with an electrical load attached. in addition the waste heat can be collected to heat a fluid or gas to make mechanical and electrical power. The multi-stacked cell in FIG. 14 will produce a higher voltage and current depending on the amount cells stacked, and the heat and surface area. The EER Fuel cell in FIG. 14 produces both exothermic heat and electricity at the same time. The heat required to heat the cell of FIG. 14 can be RF, inductive heaters, resistive heaters, gas flame heaters, solar or other heating sources. The RF feedback loop is preferred.

FIG. 15 is a thermocouple fuel cell that concerts electricity directly using hydrogen, deuterium gas or liquid in a dry cell or wet cell with lithium, lithium chloride or another form of lithium. The preferred heat source is RF but other heat sources can be used. The electrodes shown are in series to increase the voltage level. If the same cells were wired in parallel it would increase the current (not shown). The dimpled surface increases the surface area. Stranded wire or metal foam or metal powders can also be used. Any combinations of materials in FIG. 14 can be used as well as other transitional metals in any of a plurality of combinations. The invention uniquely produces electricity directly or in combination with using the waste heat to heat a gas or liquid to spin a turbine to generate electricity.

Another novelty of the invention is using fine stranded wire such as nickel or Titanium or a blend or other transitional materials that soak hydrogen and co-extruding them with a polymer with Lithium and or metal powders such as copper and iron or rhodium to make a roll of solid fuel that is motor driver into a RF reactor zone to produce a EER reaction as outlined in FIG. 20,21. Another novelty of the invention if a polymers is used such as Polyethylene that consist of four hydrogens and 2 carbons, when heated by the RF or other heating sources the hydrogen is soaked into the metal while the carbon uses the Nickel or Copper as a host to form graphene on the surface of the wire to produce a valuable continuous roll of graphene wire that is crosslinked by the RF during the formation of the graphene coating to produce one of the strongest and conductive wires in the world. The graphene can also enhance the EER reaction by applying a stress on the surface of the wire during H2 or D2 loading and absorb additional H2 or D2. In FIGS. 20,21 the RF feedback loop with a PID can be employed or a gas injection with a spark or resistive heater to melt the Pe into a EER reaction. The solid fuel allows for safely storing Lithium within the polymer. Bare lithium will explode when it comes in contact with moisture the current invention solves that problem and in addition the graphene wire can be used for electrical transmission power lines or high speed internet or faster computers. The strength of the graphene wire can be used for building stronger and lighter planes, cars and other manufactured use in computer chips etc.

Another novelty of the invention is to form single or multi-walled cross-linked graphene tube from several feet to several miles long by taking an extruded polymers With H2 and carbon with or without lithium to generate a EER furnace. The polymer extrusion with a thin metalize coating of nickel or other host materials such as copper over the polymer extrusion will for a graphene tube.

When the polymer is put under heat by RF or other means the H2 from the polymer will off gas and heat will cause the carbon to form carbon bonds to the nickel or copper host to form a graphene host on the inner and outer walls of the nickel tubes to form stiff carbon, graphene crosslinked tubed at elevated temperatures with or without oxygen as out in a cross section view in FIG. 22, FIG. 23. In FIG. 22 the strands of polymers were metalized in single strands and in FIG. 23 the final outside metalized process was done in a bundle to form an outside bundle or metalized materials that form an outside and inside bundle of graphene instead of a single or multi-walled tub it form a bundle of tubes of multi-walled graphene tubes joining the tubed together as outlined in FIG. 23.

The graphene single, multi, or bundled tubes can be formed as a by-product of an EER furnace fuel or by electric or gas furnaces with methane or other carbon gases sources. The advantage of a poly-extrusion each time the metalized coating is applied and polymer extrusion can be performed over the metalized coating to build an unlimited multi-walled graphene tubes over and over again one inside the other in a continuous process of plastic extrusions with metalized coatings. One metalized coating process over plastic would be a carbonyl gases process that can apply a nickel coating at low melting temperatures with 1,000's of feet of continuous roll to roll processing to reduce the cost of producing highly conductive and stiff graphene multi-walled graphene wire with super conductive properties with cross-linked carbon bonding for 1,000's of feet long for faster computer speeds at higher frequencies and current carrying capacities. The RF plasma helps to cross-link the graphene tube but other heating methods can be used such as gas or electric heating.

The Nickel Carbon can be made by a number of different processes, including atomization from melts or precipitation from solutions. However, these techniques tend to give relatively large particles and can be difficult to control economically at fine particle sizes. The nickel carbonyl gas process on the other hand tends to produce much finer particles, and with sufficient production know-how plus the latest computerized process controls, the particles produced can be precisely controlled to very accurate shapes and tolerances. Materials to make a good graphene surface graphene wire, strips and sheets, wherein: the metal conductor is used, it can be coated with scandium, titanium, silver, chromium, manganese, iron, cobalt, nickel, copper, zinc, dry, wrong, silver, keyhole, technetium, ruthenium, wrong button, silver, cadmium, lutetium, hafnium, tantalum, tungsten, rhenium, osmium, iridium, molybdenum, gold, and other metal coating line.

The nickel carbonyl gas process is used as a way of refining impure nickel. Nickel reacts with carbon monoxide to form nickel carbonyl gas (Ni(CO)₄), which can be decomposed back to nickel metal at moderate temperatures with the recovery of carbon monoxide. Using thermal shock decomposition, fine or extra fine nickel powders can be made. Refineries in North America and Britain can each process up to 50,000 tonnes per year of nickel in his way, producing a wide range of different products. The use of such large volumes of carbonyl gas in the refineries allows the economic production of a range of nickel powders. New products can also be made by using the gas stream essentially as a coating medium. These new products include nickel coated graphite particulates, nickel coated carbon fibers and the large scale commercial production of high porosity nickel foam. Another benefit is that the process has no real waste products, with used gas is recycled back into the main refinery process. Plasma generated by the RF in a PID loop will enhance the graphene growth at 1,000 C.

A novel RF plasma can be used during carbonyl coating a polymers molded shapes or just a carbonyl nickel coated polymer process vs the standard CVD process as outlined in application US 20130140058 the carbonyl process is a better choice than Chemical Vapor Deposition (CVD) or exfoliation due to cost and waste materials and size of parts. The polymer host can be coated with carbonyl nickel and then when placed in a EER chamber the surface can be enhanced with RF plasma and surface texture increased by the EER mechanism as outlined in FIG. 5 that will enhance graphene surfaces for better solar cells, battery electrodes, super capacitors, fibers for concrete and building materials for planes and cars as out lined in FIG. 24. The graphene will attached to the surface of the nickel, lithium and other metals such as copper or Fe during heating and form a graphene coating on the surface of the nickel to hold its shape past the nickels melting point. The graphene surface coating with stress the nickel surface tension to enhance the EER reaction and the graphene will soak the hydrogen as an electrical charge for storage.

### BRIEF DESCRIPTION OF THE DRAWINGS

FIG. 1 is a block diagram of an RF PID control system that keeps reaction microwaves in a constant state of harmonic resonance oscillation.

FIG. 2 is an isometric view of a reactor that uses microwaves as a heat source and RF power to harmonically keep the RF oscillations in a constant state of oscillation.

FIG. 2a is a cutaway view of the reactor of FIG. 2.

FIG. 3 is a schematic illustration of a Face-Center Cube (FCC) or other transitional metal structure that soaks up hydrogen with or without ferromagnetic properties.

FIG. 4 is a schematic illustration showing an oscillating FCC lattice loaded with hydrogen and the presence of lithium.

FIG. 5 is a photo taken from a book “Nuclear Transmutation The Reality of Cold Fusion,” written by Tadahiko Mizuno.

FIG. 6 is a cutaway isometric view of a reactor chamber in a ceramic tube or sprayed ceramic coating.

FIG. 7 is a cutaway view of an RF reactor that has a transmitter, receiver, and a heat exchanger with a gas supply.

FIG. 8 is a schematic illustration of an RF reactor with a helix RF coiled wave guide that puts the RF in a rotating helix electromagnetic oscillation.

FIG. 8a is a top view of the RF reactor of FIG. 8 showing microwaves in a wave guide alternating from different directions.

FIG. 9 is a cutaway view of an RF reactor inside chamber with a gas pressure vessel.

FIG. 10 shows an electromotive thruster or EM drive for spacecraft.

FIG. 11 shows a pressurized electrochemical wet cell using a DC power supply and a reverse protection blocking diode in deuterium fluid or other fluids with an electrolyte.

FIG. 12 lists mixtures of metal powder, foam, foil, and solid materials used to produce a cathode and anode EER reactor.

FIG. 13 shows a thermoelectric thermocouple EER cell using a hydrogen gas or deuterium gas or liquid with lithium chloride, or lithium salts, to produce electricity directly.

FIG. 14 shows a multi-stacked thermoelectric thermocouple made up of foam or sintered materials under compression.

FIG. 15 shows a thermocouple EER fuel cell that uses daisy chained anode and cathode materials such as the materials illustrated in FIG. 12.

FIG. 16 is a cutaway view of an array of stacked thermocouple materials to form a sintered section for microwaves to penetrate the thermocouple array to produce electricity directly.

FIG. 16a shows the current flow through the EER thermocouple with an EER heat reaction on the surface of the thermocouple material.

FIG. 17 is a profile view of FIG. 16.

FIG. 18 shows an EER reactor that makes electricity directly using a P-type and N-type semiconductor material.

FIG. 19 shows an EER thermoelectric module that converts an EER directly to electricity.

FIG. 20 shows an EER reactor that uses stranded wire that is co-extruded with a polyethylene wire with lithium and metal powders.

FIG. 21 is a cutaway view of reactor 77 of FIG. 20.

FIG. 22 shows a polymer with a novel RF plasma coated carbonyl coating or a standard carbonyl coating over a polymer shape to form a tube for a EER reactor fuel.

FIG. 23 shows a cluster of multi-walled or single walled graphene tubes joined together by a carbonyl coating.

FIG. 24 shows a polymer and a Ni or copper coating that is put under heat to form graphene on the surface.

FIG. 25 is a cut away view of polymer fuel 75 of FIG. 20.

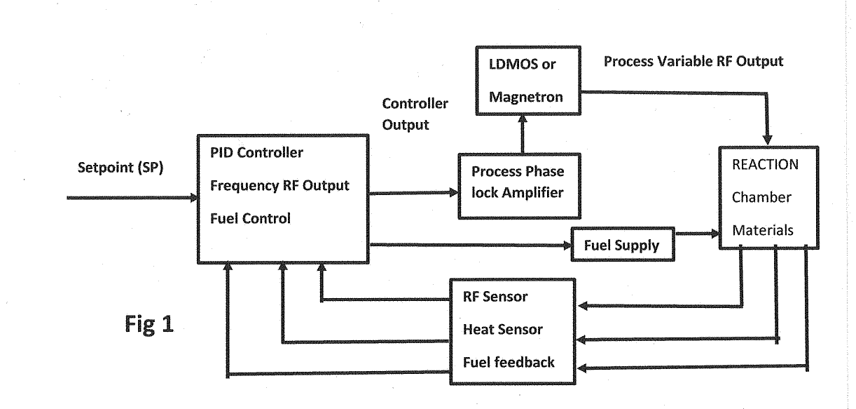

### DETAILED DESCRIPTION OF PREFERRED EMBODIMENTS

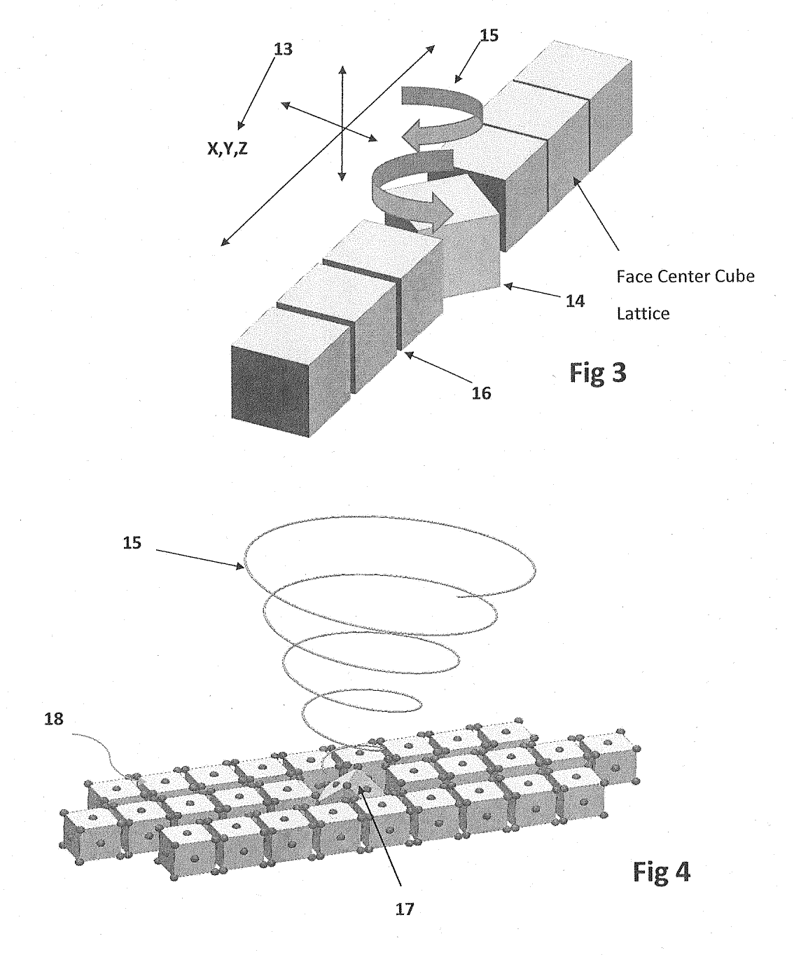

FIG. 3 illustrates a Face-Center Cube (FCC) or other transitional metal structure that soaks up hydrogen with or without ferromagnetic properties, and FIG. 4 shows an oscillating FCC lattice loaded with hydrogen and the presence of lithium. When the structure or lattice illustrated in FIGS. 3 and 4 is vibrated in 3D directions due to heat and the presence of lithium or hydrogen gas pressures, the magnetic polarity of the FCC or HCP causes a magnetic dipolar switching where the same magnetic polarity causes a FCC or HCP particle spin due to the repelling magnetic effect on the nearby FFC or HCP cube, which prevents re-alignment in a manner analogous to the manner in which an osculating magnetic switching motor creates a hot liquid vortex of metal that produces friction and heat, or the manner in which a magnetic stirrer produces a Vortex in a glass beaker of water. The FCC or HCP cubes, or other types of metals, spin faster than they can align until they again reach equilibrium as the lattice cools down due to harmonic and magnetic re-alignment. The goal of the invention is to prevent magnetic alignment of the lattice and to generate as many vortices as possible to generate heat using a microwave feedback harmonic locked loop. Heat and magnetic fields cause liquid lithium to swirl rapidly, an effect that is useful in fusion or exothermic reactors. The transitional metals switch ferromagnetically within the lithium vortex or swirl to set the FFC or HCP cubes in motion as a subatomic motor to heat up the lattice at microwave speed and build a liquid metal vortex. The lattice melted vortex will spin in the direction of or counter to the lithium spin depending on the conditions and will most likely be affected by the Earth's axis spin. Depending on location on the Earth or in space, the lithium spin rotation direction is most likely random or the direction of the lithium vortex.

Metal hydride microwave (MW) heating of metal hydrides is taken into consideration for the immediate emission of hydrogen in their use as a hydrogen storage material. MW heating of the hydrides having metallic bonding, such as a Ti—H, or Zr—H system, are a good MW absorber, and are capable of heating rapidly, but nickel and a blend of different ferromagnetic metals are preferred. Helix microwave guides with switching-timed DC pulses or AC microwave signals will improve the electromotive forces on the surface of metal foils and powders to improve the Vortex effects and increase exothermic reactions within a hydrogen plasma. The reaction control mechanism can work on EERs in a dry or wet Pons and Fleischman type of electrolysis wet cell with deuterium, lithium, Pt anode and Pd, Ru cathode electrodes, and a blocking diode between the RF and the DC power cell, illustrated in FIG. 11. The ionized gas develops a plasma antenna that can transmit and receive RF within the gas.

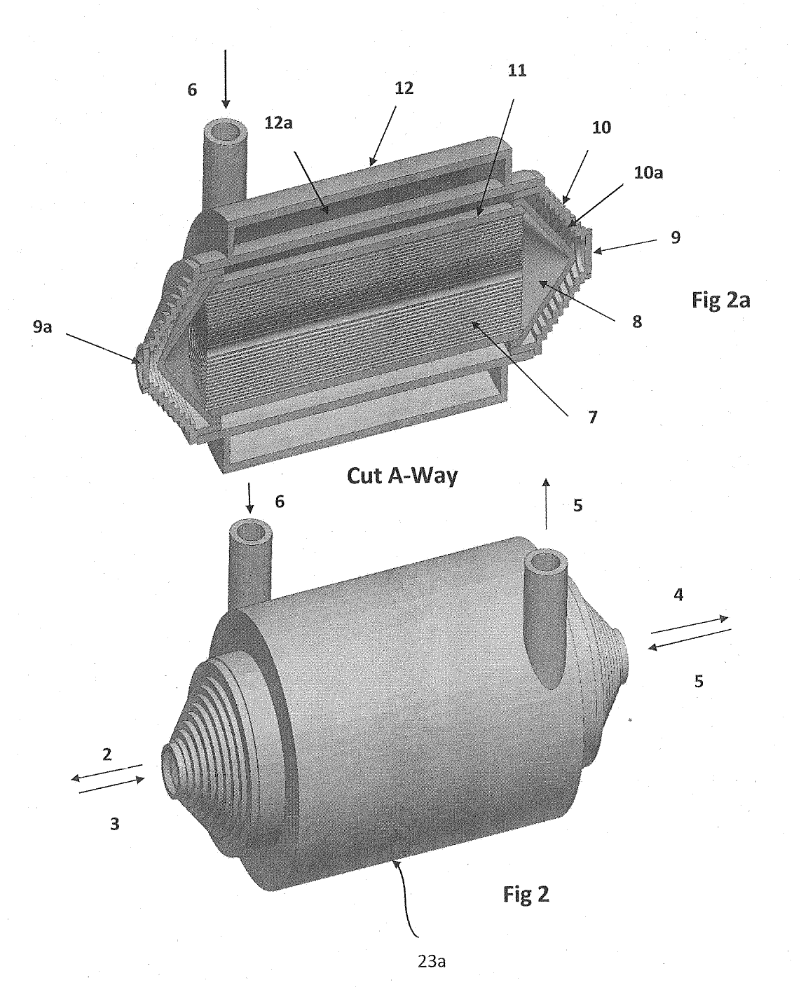

FIG. 2 shows a reactor that uses microwaves as a heat source and RF power to harmonically keep the RF oscillations in a constant state of oscillation. Reference numbers 6 and 5 indicate the input and exhaust of a heater and cooled heat exchanger that sends the heated gas or fluid to a rotating turbine to generate electrical power. Reference numbers 4,5,2,3 indicate passage of microwaves through a window 9 (shown in FIG. 2a) that allow the microwaves to pass while maintaining a gas pressure within the reactor. The window can transmit and receive microwaves from the sensor and transmitter to produce a harmonic reaction. Number 23a is the outside reactor housing.

FIG. 2a is a cutaway view of the reactor of FIG. 2, in which reference number 7 indicates a core reactor that is made up of ceramic honeycomb material coated with catalytic transitional metals such as Pd, Ni, Ti, Cu, Ru with lithium and a pressurized gas such as hydrogen, deuterium, and natural gas. Core 7 can also be a coated high temperature knitted metal with transitional materials and lithium and pressurized gases. Reference number 8 indicates a waveguide to deliver and receive RF signals. Reference number 9 indicates the above-mentioned window, which is made of a material that allows RF to pass but holds back gas pressure. 10 indicates a metal heat sink that transfer heat from the reactor but blocks internal RF. 11 refers to a ceramic tube that allows RF to pass and acts as an insulator to prevent 10 from melting. 12 refers to an outside heat exchanger. 12a indicates the inside metal wall of the heat exchanger. 6 indicates a gas or fluid heat exchanger input. Both windows 9 and 9a serve as an RF input that heats the reactor from both sides and alternate their pulses to keep the RF emitted from the reactor in a constant state of oscillation.

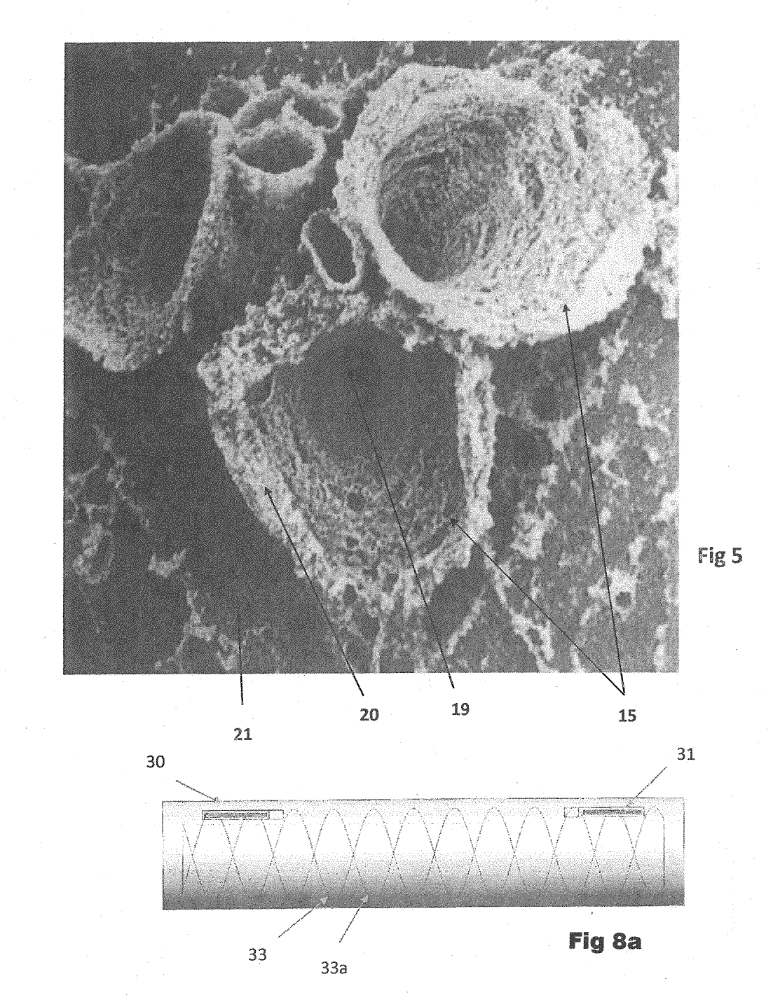

As explained above, FIG. 3 shows a Face Center Cube (FCC) example in a state of oscillations with the presence of heat, gas pressure and lithium and other materials in the right conditions. Reference number 14 indicates a ferromagnetic pole switch that spins into a vortex 15 in an oscillation 13 with lattice oscillations and gaps 16. FIG. 4 shows an FCC lattice loaded with hydrogen and the presence of lithium to create a directional 15 vortex. 17 indicates a rotating FCC that spins in rotations in the MHz to THz range that heats FCC in a friction state. 18 is hydrogen. FIG. 5 is a photo taken from a book “Nuclear Transmutation The Reality of Cold Fusion,” written by Tadahiko Mizuno, Translated by Jed Rothwell, page 102. The picture is a Gold Cathode using a scanning electron microscope at 2000×. The picture is a melted vortex that was developed by a switching FCC cube that had a ferromagnetic spin. Reference number 19 indicates the center of the vortex, 20 refers to the top wall of the vortex, 21 indicates the flat surface of the gold cathode, and 15 indicates melted vortices that were cooled with a fluid.

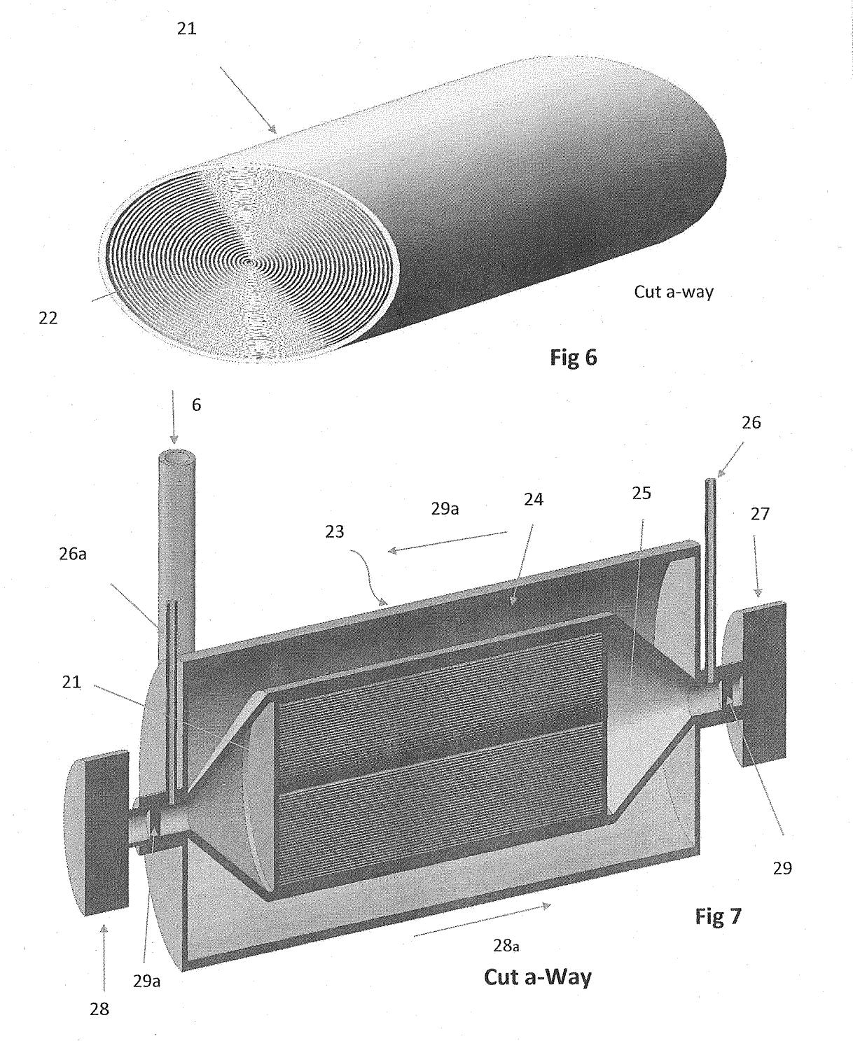

FIG. 6 shows a reactor chamber in a ceramic tube or sprayed ceramic coating. Number 22 can be a honeycomb ceramic material coated with transitional materials and conductive metals with lithium and a gas such as hydrogen, deuterium, or natural gas that turns the reaction into heat to be used to convert into an energy or a solid state thermoelectric fuel cell.

FIG. 7 is a cutaway view of an RF reactor that has a transmitter, receiver, and a heat exchanger with a gas supply. 21 indicates the reactor in a ceramic housing, 23 indicates the outside housing of the heat exchanger, 24 indicates the inside housing of the heat-exchanger, and 25 indicates the metal RF wave guide that directs the RF into the reactor materials. 26 and 26a indicates an input and exhaust to the fuel supply. 27 and 28 indicate an RF magnetron or LDMOS's RF solid state power transistor transmitter or receiver. 29 indicates a ceramic, high temperature glass or other RF pass-through materials to allow RF to pass while holding back internal gas pressure with high temperature seals (not shown). 28 and 29 indicate an RF check valve to prevent damaging RF reflections (which are not shown).

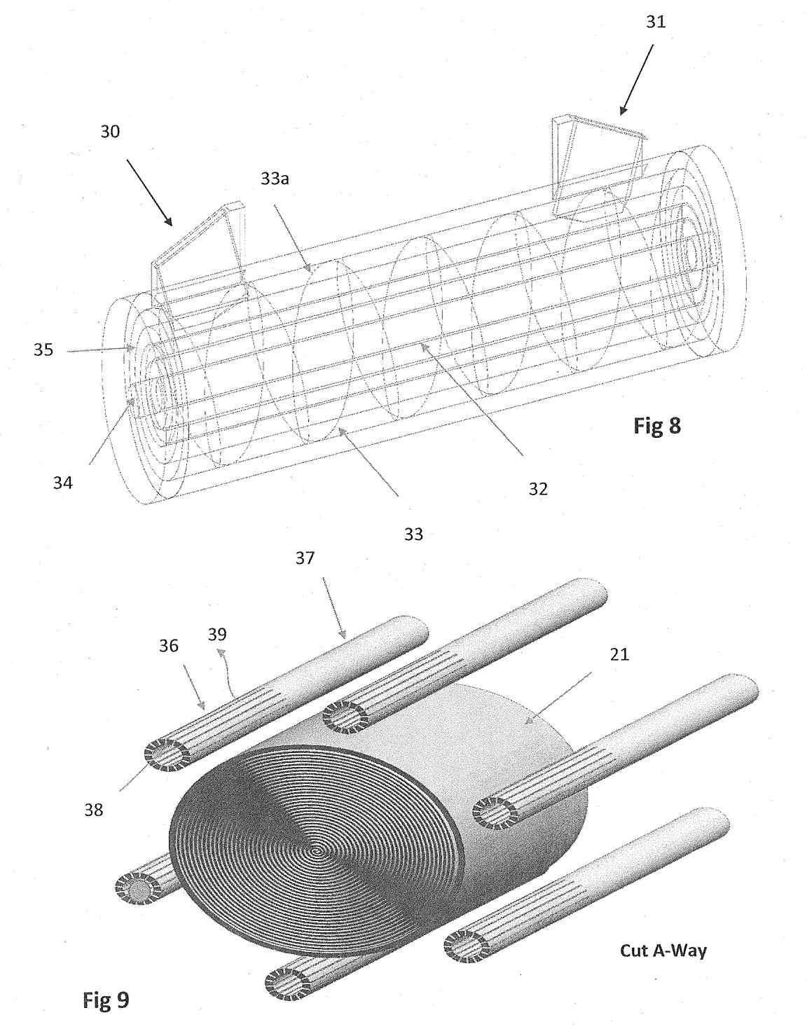

FIG. 8 shows an RF reactor with a helix RF coiled wave guide that puts the RF in a rotating helix electromagnetic oscillation. 30 and 31 indicate angled RF inputs and sensors that delivers the RF in counter or same RF helix rotations to improve cross cutting electromotive force (EMF) reactions. 32 and 33a indicate RF helix waves coming from two different directions in a helix forming wave guide. 34 indicates a center tube that can be a perforated gas supply of polyethylene with or without lithium, nickel, copper powders and/or graphene. 35 refers to a waveguide chamber.

FIG. 8a is a top view of the RF reactor of FIG. 8 showing microwaves in a wave guide alternating from different directions. Due to the mechanical arrangement, the microwaves do not interfere or reflect back into the magnetron to damage the transmitter 33 and 33a indicate tihe microwave waveforms that can be AC or pulsed DC RF.

FIG. 9 is a cutaway view of an RF reactor inside chamber with a gas pressure vessel (not shown). The reactor outside ceramic housing is indicated by 21. Number 37 represents a solid and perforated ceramic or high temperature material that contains extruded polyethylene and that is heated by the RF and reactor heat. The hydrogen in the polyethylene is released through the perforated holes, slots, or filter foam to release the H2 gas into the reactor, and the RF and reactor heat turns the remaining polyethylene carbon into crosslinked graphene that is pushed by extrusion into a holding chamber (not shown) as a valuable waste by-product. Number 38 indicates holes that are small enough to allow the H2 gas to pass while holding back the carbon. 39 indicates gas escaping the membrane tube. The perforated ceramic supply tubes 37 contain fine copper or nickel wires, foil, mesh, or foam (not shown) that can be pulled through the tubes with the melted poly fuel to act as a graphene template to grow graphene on the wire as the hydrogen leaves the poly under melting heat from the RF power to fill the chamber 21 with H2 reactive gas pressure. The graphene with grow on the pulled wire surfaces from the carbon in the poly fuel, and will cross link at elevated reaction temperatures with the presence of the RF. The host template wire can have a positive or negative charge to assist in the crosslinked graphene. The wire can be single strand to multi-strand host wire.

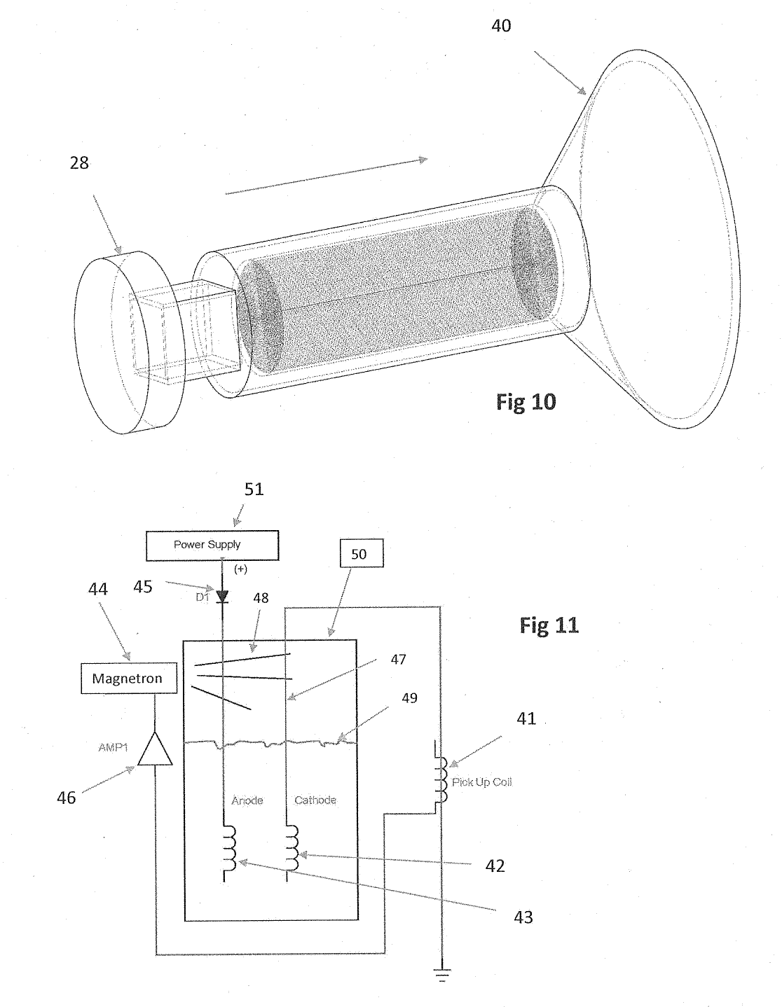

FIG. 10 shows an electromotive thruster or EM drive for spacecraft. The microwaves produced from the EER reactions helps to amplify the input microwave RF to increase and improve thrust forces. The waste microwaves from the reactor add additional power to the thruster. The reflective microwaves inside the waveguide 40 produce thrust.

FIG. 11 shows a pressurized electrochemical wet cell 50 using a DC power supply 51 and a reverse protection blocking diode 45 in deuterium fluid 49 or other fluids with an electrolyte such as lithium salt, lithium chloride, and Pt, Pd, Ru, or Ni electrodes. An RF plasma 48 above the fluid level 49 induces an RF microwave signal into the lattice of the electrodes as a feedback signal to enhance the cell's reaction. A pick up coil 41 detects the microwaves signal coming off the EERs or other electrochemical ground path reactions and sends the signal back to the amplifier 46, where it is matched to the microwave trigger reaction coming from the lattice to create a harmonic oscillating resonance lattice reaction in a controlled PID feedback loop. The above cathode or anode can act as an antenna to transfer the RF into the lattice in the electrochemical cell with different shaped electrodes (not shown). The electrode in the electrolyte fluid carries ions and current between electrodes to load hydrogen into the cathode. The ionized gases above the electrode fluid level create an RF plasma that can also load hydrogen into the cathode above the fluid line. A catalyst membrane (not shown) converts the H2/O2 from the electrolysis fluid supplied plasma gas back to a fluid to prevent an explosion of H2/O2 mixtures under gas pressure. Additional gases can be used with the RF plasma such as hydrogen, deuterium gas, and natural gas under pressure to enhance the reactions. The RF plasma source can be DC pulses or an AC signal.

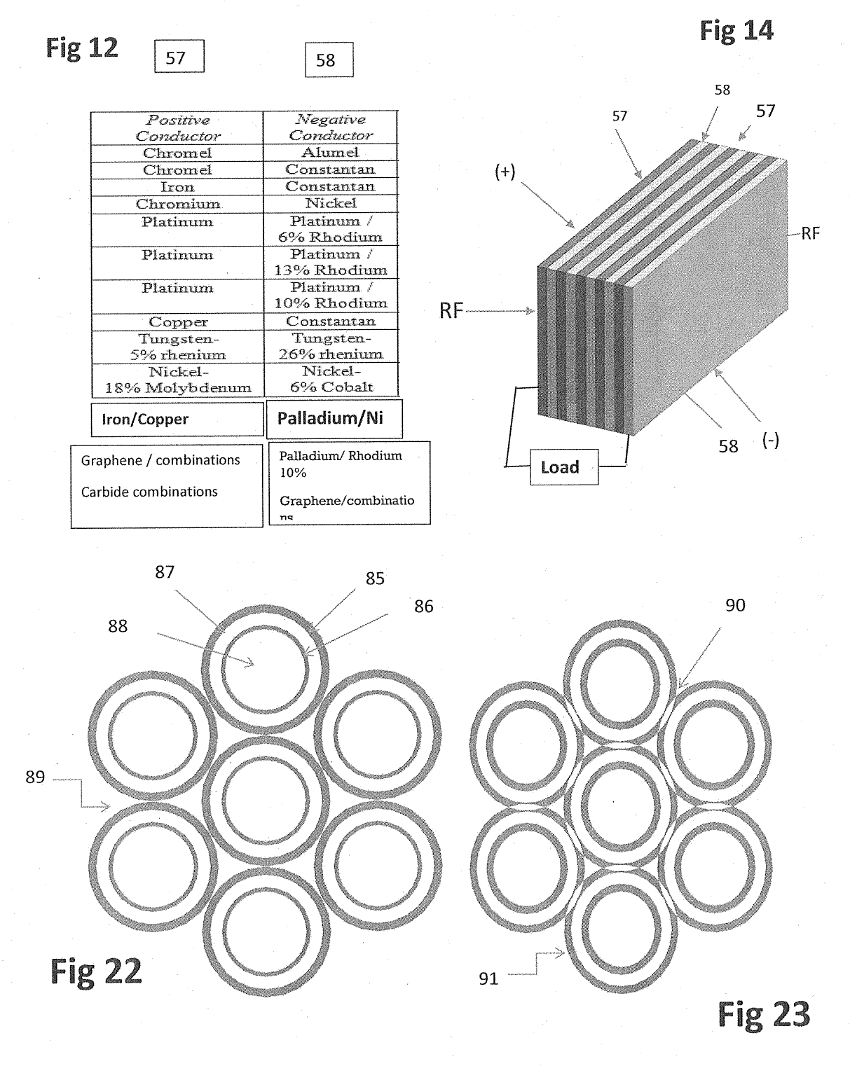

FIG. 12 lists mixtures of metal powder, foam, foil, and solid materials used to produce a cathode and anode EER reactor to produce electricity directly using heat from a heat source and hydrogen, deuterium, lithium chloride, or lithium salt to produce a wet or dry EER cell. Column 57 lists positive thermocouple materials and column 58 lists negative thermocouple materials.

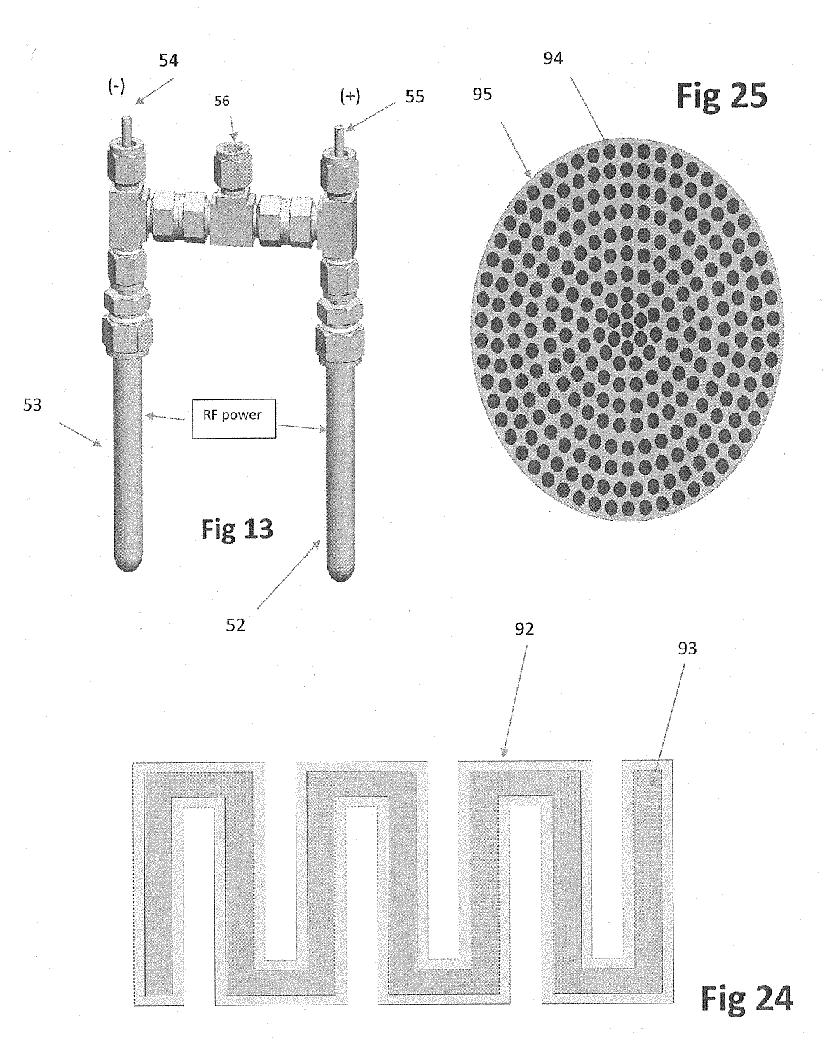

FIG. 13 shows a thermoelectric thermocouple EER cell using a hydrogen gas or deuterium gas or liquid with lithium chloride, or lithium salts, to produce electricity directly. 52 indicates ceramic tubes that are filled with a combination of materials such as those listed in FIG. 12. The contents of cell 52 are positive in nature and the contents of 53 are negative in nature. An RF power source heats up the contents of cells 52 and 53 at the same time or one at a time, or just the contents of one cell. 55 indicates a positive electrode, 54 indicates a negative electrode and 56 indicates a gas or fluid fuel input.

FIG. 14 shows multi-stacked thermoelectric thermocouple made up of foam or sintered materials under compression, which are welded or heated to form a reaction cell with the presence of lithium, hydrogen, deuterium, or lithium chloride. The cell uses a low energy EER to produce a stepped voltage similar to a battery cell except that the voltage is produced with dissimilar materials subjected to heat. 57 indicates a positive stacked electrode cell and 58 indicates a negative cell in series. Electrodes 57 and 58 can be any combination of materials listed in the two columns of FIG. 12 to produce a thermocouple cell.

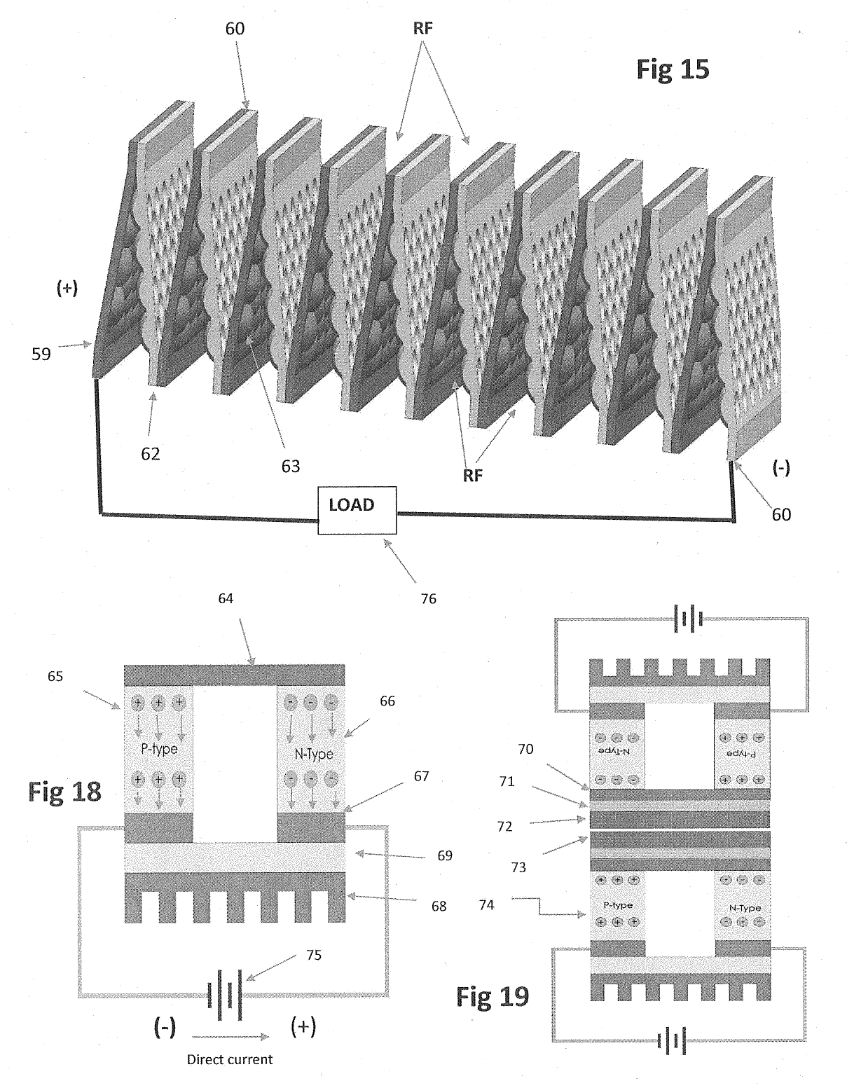

FIG. 15 is a thermocouple EER fuel cell that uses daisy chained anode and cathode materials such as the materials illustrated in FIG. 12, although it will be appreciated that other metals can be used.

The cells are heated with an RF power source with lithium. The current configuration is in series but it can also be constructed in parallel for higher current density. The electrode 59 is the anode and 60 is the cathode. The electrodes are attached at junction points 60,62 by spot welding, friction, stir welding, etc. The electrodes can be flat co-deposition materials or dimpled for a higher surface area as shown as 63. The dimples help absorb the microwave heat energy and help reflect the RF inside of the V shaped cravats where the two materials are joined. The load 64 completes the current path. If the electrodes are made of a foam material with lithium or lithium chloride, the cathode can soak up hydrogen to store energy by placing a ceramic membrane between the electrical connection 60,62 to allow ions to flow between the electrodes. Other electrode shapes that help absorb microwave can be deposited on the electrodes, such a carbon nano wires, or the electrodes can be electroplated or chemically etched to increase the surface area on the surface of the electrodes.

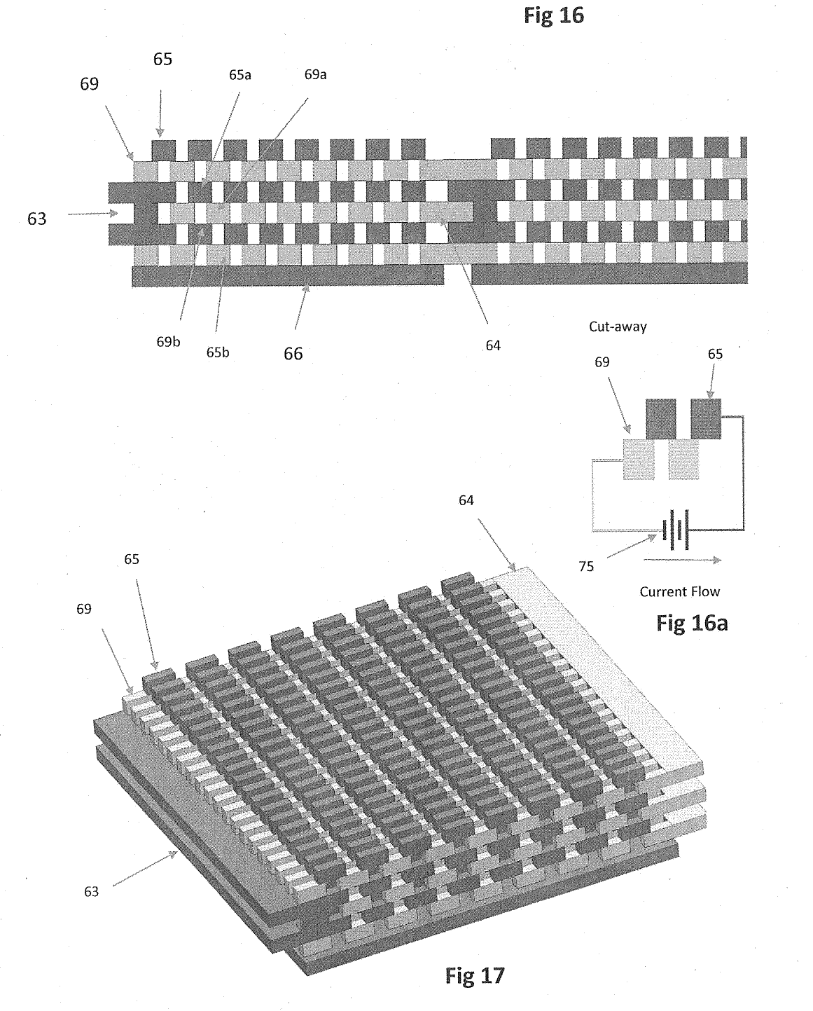

FIG. 16 is a cutaway view of FIG. 17 showing an array of stacked thermocouple materials to form a sintered section for microwaves to penetrate the thermocouple array to and from a EEG heat reaction to produce electricity directly. The sections can be manufactured with matting electrical interfaces such as 63,64 the sections are bonded electrically during manufacturing by metallic fuse bonding, etching, deposition or electorally welded. The electrical connection can be formed on all sides to be installed like floor tiles to create large surfaces for high power. The surfaces of 65 positive electrode or 69 negative electrode has a transitional metals with lithium and a form of hydrogen to produce electricity directly from the heated reaction. 66 indicates an insulator, and 65a,69a,69b,65b indicate arrays.

FIG. 16a shows the current flow through the EER thermocouple with an EER heat reaction on the surface of the thermocouple material. 69 indicates the cathode, 65 the anode, and 75 the battery or load.

FIG. 17 is a profile view of FIG. 16

FIG. 18 is an EER reactor that makes electricity directly using a P-type and N-type semiconductor material. 64 is a conductive transitional material with the presence of lithium, or lithium chloride, lithium salts and hydrogen or deuterium gases or liquids. As the EER reaction takes place on the surface of material 64 with RF or other heat sources, an EER reaction is converted directly into electricity. 65 indicates a P-type of material and 66 is the N-type to form a thermoelectric module. 67 indicates a conductor such as copper or graphene and 69 an insulator such as ceramic and 68 is a heat sink material. 75 is a battery or load. The thermoelectric module can be heated with RF or other heat sources or it can be used as a wet electro-chemical cell where the surface of 64 is a cathode and the anode is not shown. Graphene or graphite can be used with P-Type or N-Type materials to act as a better conductor and heat resistance add to other materials such as semiconductor telluride Synthesis PbTe-(0-4 mol %) SrTe doped with 2 mol % Na, with graphene, flakes or tubes.

FIG. 19 is an EER thermoelectric module that converts a an EER directly to electricity. The reaction takes place using RF energy or other heat sources as the heat source. 72 and 73 can be an anode or cathode in a wet electrochemical cell, converting the heat in the cathode directly to electricity in the presence of lithium, lithium chloride, lithium salts, deuterium, deuterium gas or and/or hydrogen gas. The heat reaction can take place between electrodes 72,73 that are comprised of transitional materials such as Nickel, Pt, Pd, Ru, Ti, Cu, Fe etc. The heat from the reactor is converted into electricity directly. 70 indicates a conductor, 71 an insulator or conductor, 72 an EER reactive surface, and 73 an EER reactive surface. Both cells 74 make electricity from the same reaction heat source.

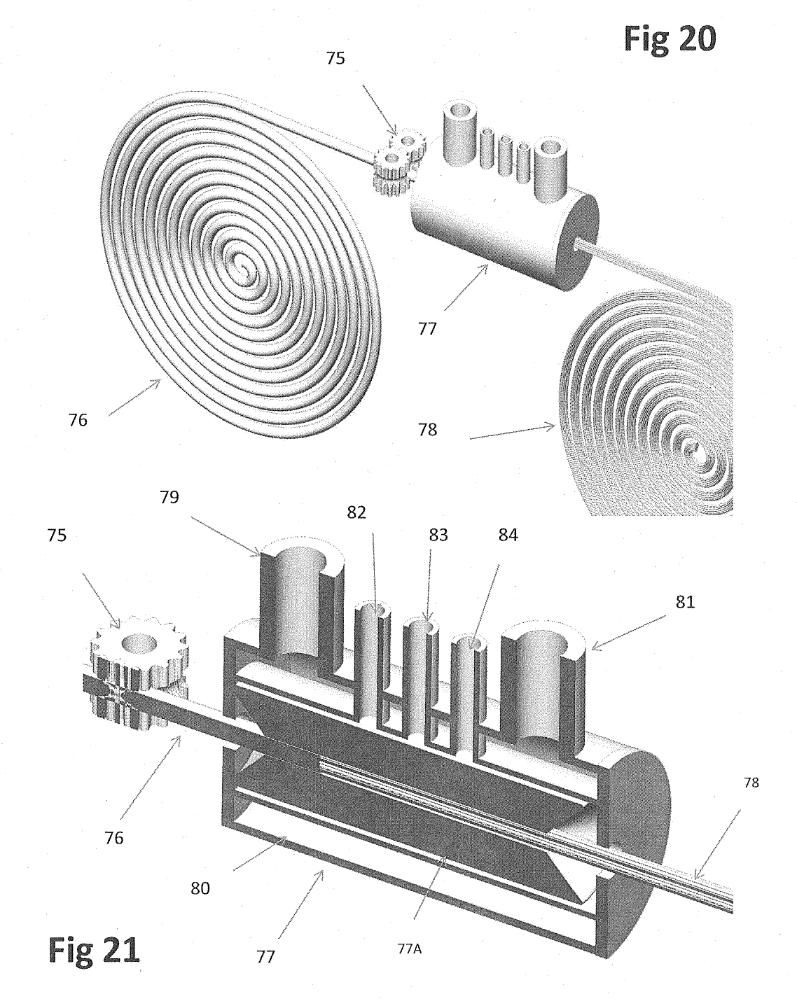

FIG. 20 is an EER reactor that uses stranded wire that is co-extruded with a polyethylene wire with lithium and metal powders such as iron, copper or other transitional metal powders or wires. The reactor is in a pressurized gas filled housing and the RF from the EER will send a reflective skin effect down the entire length of the wire to enhance a EER reaction from the wire and graphene communication. In this figure, 77 is the reactor chamber outside heat exchanger, 75 is the drive roller to drive the fuel cable into the reactor the motor is not shown that can be electric, pneumatic or magnetically driven, 76 is the polymer, lithium, wire or powder metal fuels and 78 is the melted powder or metal wire with a graphene coating.

FIG. 21 is a cutaway view of reactor 77 of FIG. 20, in which 79 in a heat exchanger return supply line from the condenser and pump and 81 is the reactor heated output line to the turbine or hot water heater. 82,84 are the RF input power and 83 is the antenna feedback sensor from the EER reaction. 78 is the spent fuel with graphene coated wire and 76 is the supply fuel to the reactor with poly as the hydrogen source and carbon as the graphene source. 75 is the drive sprocket to drive the fuel into the reactor. 77 is the reactor boiler, heat exchanger outside chamber and 80 is the inside of the heat exchanger to heat a fluid or a gas and 77a is the ceramic reactor core inside the RF waveguide.

FIG. 22 shows a polymer with a novel RF plasma coated carbonyl coating or a standard carbonyl coating over a polymer shape to form a tube for a EER reactor fuel. The polymer can be mixed with lithium and other EER fuel materials or they can be added later. 88 is the polymer 86 is the nickel 86 will be coated with graphene after it is placed in heat with or without oxygen, 87 is a second coating of polymer to form a multi-walled graphene tube over a second nickel coating. 85 is nickel before heated and 85 becomes nickel with a graphene coating after heating with an RF EER reaction or other heating sources to form a multi-walled graphene tube. 89 is a cluster of nickel coated graphene tubes to form a conductive wire or composites materials for strength. The polymer are molds to shape the graphene and fuel and carbon for the graphene.

FIG. 23 shows a cluster of multi-walled or single walled graphene tubes joined together by a carbonyl coating whereby the tubes were touching during the nickel coating and graphene was grown over the cluster to form a multi-wall cluster or multi-tube Ni, graphene tubes wires for high frequencies transmission wires, computer chips, etc. As shown in FIG. 23, 91 is the joined cluster and 90 is the touching points to form Ni between Ni coated tubes that were carbonyl coating or CVD coated.

FIG. 24 shows a polymer 93 and a Ni or copper coating 92 that is put under heat to form graphene on the surface of 92 and the polymer 93 suppliers the H2 and carbon.

FIG. 25 is a cut away view of polymer fuel 75 of FIG. 20 with or without lithium and nickel or copper wire or other materials outlined to form graphene on the surface of the wire as the polymers burn away to off gas hydrogen and carbon residue forms on the host of the Ni, Cu or other materials. 94 is the wire that gets coated with graphene and 95 is the extruded polymer that holds the wires together to form a fuel and source of carbon to grow graphene.

Although the preferred embodiments described above utilized hydrogen gas, deuterium, and natural gas, JP8, and/or polyethylene as specific examples of a hydrogen source for the gas loading, it will be appreciated that other hydrogen-containing materials such as seawater may also, or alternatively, be used as a hydrogen source. Byproducts of using seawater would be fresh water and chlorine. This and other modifications and variations of the preferred embodiments should be considered to fall within the scope of the invention.

### REFERENCES

https://physics.aps.org/story/v25/st8
http://www.iccf19.com/_system/download/poster/PS34_Kidwell.pdf
http://www.iccf19.com/_system/download/poster/PS34_Kidwell.pdf
http://www.iccf19.com/_system/download/abstract_poster/AP53_Scholkmann.pdf
http://www.enea.it/it/pubblicazioni/pdf-eai/n2-2014/rf-detection-and-anomalous-heat.pdf

I claim:

1. A radio frequency (RF) reactor for producing enhanced exothermic reactions (EERs) by hydrogen, deuterium, or hydrogen-containing-gas loading of metals containing lithium or graphene, comprising:
at least one metal lattice into which hydrogen is loaded in the presence of the graphene or lithium;
an RF power source to ionize the hydrogen and generate a hydrogen plasma that facilitates the hydrogen loading, the hydrogen loading in the presence of the graphene or lithium causing EERs that generate heat; and
software and hardware for coupling or harmonically synchronizing an output of the RF power source and an RF output of the lattice to create harmonic oscillations in a closed feedback loop that keeps the oscillations in a constant state to reduce input power and maintain a constant output power.

2. An RF reactor for producing EERs as claimed in claim 2, wherein control of the RF power source while carrying out said hydrogen loading creates a vortex that causes ferromagnetic flipping of spins within the lattice to create a microwave vortex swirl that melts nearby materials with friction heat and that also results in said harmonic oscillations to produce a reaction RF signal.

3. An RF reactor for producing EERs as claimed in claim 2, wherein the RF power source is controller to prevent the lattice from attaining harmonic equilibrium and thereby promote as many vortices and lattice oscillations, and resulting electromotive disturbances, as possible.

4. An RF reactor for producing EERs as claimed in claim 2, wherein the lattice has a Face Center Cube (FCC), Body Center Cube (BBC), or Hexagonal Close Packed (HCP) alignment.

5. An RF reactor for producing EERs as claimed in claim 1, wherein the RF source is a microwave source.

6. An RF reactor for producing EERs as claimed in claim 5, wherein the RF source is an LDMOS microwave emitter or a magnetron.

7. An RF reactor for producing EERs as claimed in claim 6, further comprising at least one feedback sensor for supplying feedback to a controller arranged to control an output frequency and/or phase angle of the RF power source.

8. An RF reactor for producing EERs as claimed in claim 7, further comprising at least one additional feedback sensor for controlling a supply of said hydrogen, deuterium, or hydrogen-containing-gas to said reactor.

9. An RF reactor for producing EERs as claimed in claim 7, wherein the controller is a proportional-integral-derivative (PID) controller.

10. An RF reactor for producing EERs as claimed in claim 7, wherein said at least one feedback sensor and/or at least one additional feedback sensor includes at least one of an RF sensor, a heat sensor, and a fuel supply sensor.

11. An RF reactor for producing EERs as claimed in claim 7, wherein the controller controls a phase angle between oscillation of the lattice and an output of a transmitter of the RF power source.

12. An RF reactor for producing EERs as claimed in claim 1, wherein the RF output of the lattice is applied to drive a space propulsion engine.

13. An RF reactor for producing EERs as claimed in claim 1, further comprising a turbine powered by the heat generated by the EERs.

14. An RF reactor for producing EERs as claimed in claim 1, further comprising a thermoelectric generator power by the heat generated by the EERs.

15. An RF reactor for producing EERs as claimed in claim 1, wherein the at least one metal lattice is made of foil, foam, wire knitted mesh, or powdered materials constructed under hydrogen, deuterium, lithium chloride, or gas pre-loaded pressures and mixed with lithium or graphene as a reaction material.

16. An RF reactor for producing EERs as claimed in claim 1, wherein the at least one metal lattice includes a stainless steel mesh wire or metal foam with a high surface area and melt temperature that is carbonyl nickel coated and placed into a high temperature vacuum chamber with methane to grow graphene on a surface of the nickel coated wire mesh, with the hydrogen from the methane being embedded on a surface of the nickel and carbon chains from the graphene on the surface of the mesh wire or metal foam acting as a host for the EERs reactions under heat and hydrogen or deuterium gas pressure loading.

17. An RF reactor for producing EERs as claimed in claim 16, wherein lithium is added to the methane for a highly conductive EER reaction surface.

18. An RF reactor for producing EERs as claimed in claim 16, therein other transitional metals are added during high vacuum furnace processing.

19. An RF reactor for producing EERs as claimed in claim 18, wherein the other transitional metals are selected from ruthenium, copper, palladium, and carbide.

20. An RF reactor for producing EERs as claimed in claim 1, wherein the at least one metal lattice is a thermoelectric thermocouple electrode included in a positive and negative electrode stack that generates electricity directly in response to the heat from the EERs generated upon application of RF power to the metal lattice.

21. An RF reactor for producing EERs as claimed in claim 20, wherein the electrodes have dimpled surfaces to increase surface area.

22. An RF reactor for producing EERs as claimed in claim 1, wherein the reactor is a Pons and Fleischman type of electrolysis dry or wet cell having a pair of electrodes include the at least one metal lattice and containing deuterium, lithium, platinum, palladium, nickel, and/or ruthenium.

23. An RF reactor for producing EERs as claimed in claim 22, wherein the reactor is a pressurized electrochemical wet cell using a DC power supply, a reverse protection blocking diode, and a liquid electrolyte containing lithium, lithium salt, or lithium chloride that carries ions and current between the electrodes, and wherein ionized gases above the electrode fluid level create an RF plasma that loads hydrogen into a cathode electrode above the fluid line.

24. An RF reactor for producing EERs as claimed in claim 23, wherein the plasma is generated by DC pulses or an AC signal.

25. An RF reactor for producing EERs as claimed in claim 23, wherein a microwave source above a fluid level of the electrolyte applies an RF trigger signal into the lattice, the electrodes acting as an antenna for the RF trigger signal, wherein a pickup coil detects an RF reaction signal coming off EERs or electrochemical ground path reactions that occur in the lattice, and wherein the RF reaction signal is matched to the RF trigger signal to create a harmonic oscillating resonance lattice reaction in a controlled PID feedback loop.

26. An RF reactor for producing EERs as claimed in claim 23, further comprising a catalyst membrane that converts hydrogen and oxygen from the electrolysis fluid supplied plasma gas back to a fluid to prevent an explosion of the hydrogen and oxygen mixtures under gas pressure.

27. An RF reactor for producing EERs as claimed in claim 1, further comprising a reaction chamber in a ceramic tube or a tube with a sprayed ceramic coating that includes transitional materials and conductive metals with lithium to form said lattice.

28. An RF reactor for producing EERs as claimed in claim 27, wherein the RF power source supplies RF power to the reaction chamber through a waveguide that directs the RF power into the lattice.

29. An RF reactor for producing EERs as claimed in claim 28, further comprising RG pass-through windows that allow RF to pass while holding back internal gas pressure with high temperature seals.

30. An RF reactor for producing EERs as claimed in claim 27, further comprising a pressurized gas source for supplying the hydrogen, deuterium, or hydrogen-containing-gas to said reaction chamber.

31. An RF reactor for producing EERs as claimed in claim 27, wherein the reactor further includes a material containing extruded polyethylene arranged to be heated by RF and heat from the reaction chamber, the polyethylene releasing hydrogen into the reaction chamber through perforated holes, slots, or filter foam that permit passage of the hydrogen but not carbon from the polyethylene, and the RF and heat from the reactor turning the remaining polyethylene carbon into crosslinked graphene that is pushed by extrusion into a holding chamber for extraction from the reactor as a valuable by-product.

32. A radio frequency (RF) reactor for producing enhanced exothermic reactions (EERs) by hydrogen, deuterium, or hydrogen-containing-gas loading of metals containing lithium or graphene, comprising:
at least one metal lattice into which hydrogen is loaded in the presence of the graphene or lithium; and
a thermal energy source for applying thermal energy to the at least one metal lattice to ionize the hydrogen and generate a hydrogen plasma that facilitates the hydrogen loading, the hydrogen loading in the presence of the graphene or lithium causing EERs that generate heat,
wherein the at least one metal lattice is a thermoelectric thermocouple electrode included in a positive and negative electrode stack that generates electricity directly in response to the heat from the EERs generated upon application of thermal energy to the metal lattice.

33. An RF reactor for producing EERs as claimed in claim 32, wherein the thermal energy source is at least one of an inductive heater, resistive heater, gas flame heater, solar collector, or RF emitter.

34. A radio frequency (RF) reactor for producing enhanced exothermic reactions (EERs) by hydrogen, deuterium, or hydrogen-containing-gas loading of metals containing lithium or graphene, comprising:
at least one metal lattice into which hydrogen is loaded in the presence of the graphene or lithium; and
a thermal energy source for applying thermal energy to the at least one metal lattice to ionize the hydrogen and generate a hydrogen plasma that facilitates the hydrogen loading, the hydrogen loading in the presence of the graphene or lithium causing EERs that generate heat,
wherein the reactor is a pressurized electrochemical wet cell using a DC power supply, a reverse protection blocking diode, and a liquid electrolyte containing lithium, lithium salt, or lithium chloride that carries ions and current between the electrodes, and wherein ionized gases above the electrode fluid level create an RF plasma that loads hydrogen into a cathode electrode above the fluid line,
wherein the plasma is generated by DC pulses or an AC signal, and
wherein a microwave source above a fluid level of the electrolyte applies an RF trigger signal into the lattice, the electrodes acting as an antenna for the RF trigger signal, wherein a pickup coil detects an RF reaction signal coming off EERs or electrochemical ground path reactions that occur in the lattice, and wherein the RF reaction signal is matched to the RF trigger signal to create a harmonic oscillating resonance lattice reaction in a controlled PID feedback loop.

35. An RF reactor for producing EERs as claimed in claim 34, further comprising a catalyst membrane that converts hydrogen and oxygen from the electrolysis fluid supplied plasma gas back to a fluid to prevent an explosion of the hydrogen and oxygen mixtures under gas pressure.

36. A radio frequency (RF) reactor for producing enhanced exothermic reactions (EERs) by hydrogen, deuterium, or hydrogen-containing-gas loading of metals containing lithium or graphene, comprising:
a reaction chamber including at least one metal lattice into which hydrogen is loaded in the presence of the graphene or lithium; and
a thermal energy source for applying thermal energy to the at least one metal lattice to ionize the hydrogen and generate a hydrogen plasma that facilitates the hydrogen loading, the hydrogen loading in the presence of the graphene or lithium causing EERs that generate heat,
wherein the a reaction chamber in a ceramic tube or a tube with a sprayed ceramic coating that includes transitional materials and conductive metals with lithium to form said lattice,
wherein the RF power source supplies RF power to the reaction chamber through a waveguide that directs the RF power into the lattice, and
further comprising RF pass-through windows that allow RF to pass while holding back internal gas pressure with high temperature seals.

37. An RF reactor for producing EERs as claimed in claim 36, further comprising a pressurized gas source for supplying the hydrogen, deuterium, or hydrogen-containing-gas to said reaction chamber.

38. An RF reactor for producing EERs as claimed in claim 36, wherein the reactor further includes a material containing extruded polyethylene arranged to be heated by RF and heat from the reaction chamber, the polyethylene releasing hydrogen into the reaction chamber through perforated holes, slots, or filter foam that permit passage of the hydrogen but not carbon from the polyethylene, and the RF and heat from the reactor turning the remaining polyethylene carbon into crosslinked graphene that is pushed by extrusion into a holding chamber for extraction from the reactor as a valuable by-product.
